(19) United States
(12) Patent Application Publication
(10) Pub. No.: US 2014/0083840 A1
(43) Pub. Date: Mar. 27, 2014

(54) Film Deposition Apparatus and Film Deposition Method

(71) Applicants: Kuei-Sen HSIAO, Nantou (TW); Yu-Chueh Chou, Nantou (TW); Shih-Hao Huang, Nantou (TW)

(72) Inventors: Kuei-Sen HSIAO, Nantou (TW); Yu-Chueh Chou, Nantou (TW); Shih-Hao Huang, Nantou (TW)

(73) Assignee: National Chi Nan University

(21) Appl. No.: 13/614,002

(22) Filed: Sep. 13, 2012

(30) Foreign Application Priority Data
Jan. 31, 2012 (TW) 101103054

(51) Int. Cl. C23C 14/46

(52) U.S. Cl. CPC C23C 14/46
USPC 204/192.11; 204/298.04

(57) ABSTRACT

A film deposition apparatus includes: a chamber including a chamber wall that is formed with a window; a target holder disposed in the chamber for supporting a target; a radio frequency power device; a pole plate unit disposed in the chamber and including a first pole plate that is electrically connected to the radio frequency power device, and a second pole plate for supporting the substrate, the first and second pole plates being disposed at two opposite sides of the target holder; a vacuum device to extract air from the chamber; and a pulsed laser device to generate a laser beam capable of bombarding the target through the window.

### CROSS-REFERENCE TO RELATED APPLICATION

This application claims priority of Taiwanese application no. 101103054, filed on Jan. 31, 2012.

### BACKGROUND OF THE INVENTION

1. Field of the Invention

This invention relates to a film deposition apparatus and a film deposition method.

2. Description of the Related Art

With the innovation of film deposition technology, various film deposition methods have been published. Depending on the requirements for physical or optical characteristics of a film, different film deposition methods are adopted to achieve a desired film quality.

Currently, with the development of optoelectric devices, such as solar cells and semiconductors, methods for preparing a transparent conductive oxide (TCO) film have attracted much attention in the industry. Indium tin oxide (ITO) and aluminum zinc oxide (AZO) are alloy targets that are manufactured by doping procedure and that are used to improve characteristics of TCO. Moreover, a high energy device, such as a pulsed laser deposition (PLD) system, can be used to deposit TCO with better quality. However, PLD should be conducted at a high vacuum condition and thus a high vacuum device capable of achieving a high vacuum degree is required.

Lei ZHAO et al. disclosed a pulsed laser deposition technology for preparing a zinc oxide thin film, in which a high vacuum degree (10⁻⁶˜10⁻⁷ torr) is required. Thus, an ultra high vacuum device is required, thereby resulting in high costs (“Effects of temperature and pressure on the structural and optical properties of ZnO films grown by pulsed laser deposition”, Lei ZHAO, Chang-Shan X U, Yu-Xue LIU, and Yi-Chun LIU, Technological Science (2010), vol. 53, p317-321).

Accordingly, how to effectively use the pulsed laser deposition technique without requiring a high vacuum degree is a subject of endeavor in the industry.

### SUMMARY OF THE INVENTION

Therefore, an object of the present invention is to provide a film deposition apparatus and a film deposition method that can overcome the aforesaid drawbacks associated with the prior art.

According to one aspect of this invention, a film deposition apparatus comprises:
a chamber including a chamber wall that is formed with a window;
a target holder disposed in the chamber for supporting a target;
a radio frequency power device;
a pole plate unit disposed in the chamber and including a first pole plate that is electrically connected to the radio frequency power device, and a second pole plate for supporting a substrate, the first and second pole plates being disposed at two opposite sides of the target holder;
a vacuum device for extracting air from the chamber; and
a pulsed laser device to generate a laser beam capable of bombarding the target through the window.

According to another aspect of this invention, a film deposition method using the aforesaid film deposition apparatus comprises:
(a) disposing a substrate on the second pole plate;
(b) vacuuming the chamber to a working pressure using the vacuum device;
(c) activating the radio frequency power device to generate a plasma between the first and second pole plates; and
(d) activating the pulsed laser device to generate a laser beam that bombards a target held by the target holder through the window in the chamber wall to ablate the target and to deposit the ablated target on the substrate.

### BRIEF DESCRIPTION OF THE DRAWINGS

Other features and advantages of the present invention will become apparent in the following detailed description of the preferred embodiments of the invention, with reference to the accompanying drawings, in which:

FIG. 1 is a schematic diagram of the preferred embodiment of a film deposition apparatus according to this invention;

FIG. 2 is a flow chart of the preferred embodiment of a film deposition method according to this invention;

FIG. 3 shows XRD spectra for zinc oxide thin films respectively manufactured by Example 1 (E1) and Comparative example 1 (CE1);

FIG. 4 shows photoluminescence spectra for zinc oxide thin films respectively manufactured by E1 and CE1;

FIG. 5 shows a relationship between the thickness of the zinc oxide thin film and radio frequency output power;

FIG. 6 shows XRD spectra for the zinc oxide thin films manufactured by Examples 3 to 6 (E3˜E6);

FIG. 7 shows XRD spectra for the zinc oxide thin films respectively manufactured by Example 7 (E7) and Comparative example 2 (CE2); and

FIG. 8 shows XRD spectra for the zinc oxide thin films respectively manufactured by E7 and E3.

### DETAILED DESCRIPTION OF THE PREFERRED EMBODIMENTS

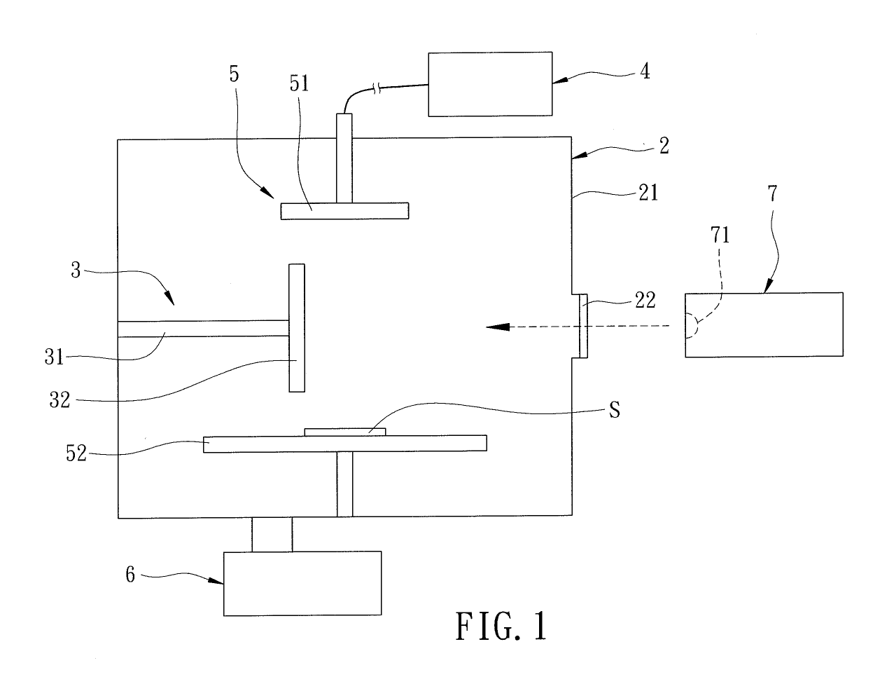

FIG. 1 illustrates the preferred embodiment of a film deposition apparatus for depositing a film on a substrate (S) according to this invention. The film deposition apparatus comprises: a chamber 2, a target holder 3, a radio frequency power device 4, a pole plate unit 5, a vacuum device 6, and a pulsed laser device 7.

The chamber 2 includes a chamber wall 21 that is formed with a window 22, and the window 22 is made of glass.

The target holder 3 is disposed in the chamber 2, and includes a rotatable target base 31 which has a free end on which a target 32 is disposed. The target 32 can be rotated with the rotatable target base 31 and is disposed on the free end of the target base 31 at a position that is capable of being radiated by a laser beam from the pulsed laser device 7. In this embodiment, the target 32 is made of a metal oxide material, such as zinc oxide, tin(II) oxide, or indium tin oxide.

The radio frequency power device 4 is used to provide a radio frequency output power ranging from 0 Watt to 300 Watt and an output frequency so as to generate a plasma by exciting gas in the chamber 2. In this embodiment, the radio frequency power device 4 is PFG 300RF from Huettinger Electronic, Inc., and has an output frequency of 13.56 MHz.

The pole plate unit 5 is disposed in the chamber 2 and includes a first pole plate 51 electrically connected to the radio frequency power device 4, and a second pole plate 52 that is grounded and used for supporting the substrate (S). The first and second pole plates 51, 52 are disposed at two opposite sides of the target holder 3. The first pole plate 51 has a size smaller than that of the second pole plate 52. In the preferred embodiment, the first and second pole plates 51 and 52 have a round shape. The first pole plate 51 has a diameter, e.g., of 5 cm, 8 cm, 12 cm or 15 cm. The diameter of the first pole plate 51 is selected depending on actual requirements. The second pole plate 52 has a diameter, e.g., 20 cm, and the distance between the first pole plate 51 and the second pole plate 52 is 6 cm.

The vacuum device 6 is used to extract air from the chamber 2. In the preferred embodiment, the vacuum device 6 is a mechanical pump capable of achieving 30 mtorr vacuum degree.

The pulsed laser device 7 includes a laser source 71 for generating a laser beam that is capable of bombarding the target 32 through the window 22. The bombarded target will be ablated and the ablated target is then deposited on the substrate (S) to form a thin film. The laser beam has a wavelength ranging from 150 nm to 1100 nm. The wavelength and laser power of the laser beam are selected based on actual requirements. In the preferred embodiment of this invention, the pulsed laser device 7 is a nano-second pulsed laser device, LS-2137U from LOTIS TII, and is capable of generating a laser beam having a wavelength of 266 nm, 355 nm, 523 nm or 1064 nm. In the examples of this invention, the wavelength is 532 nm and the laser power is 33 mJ/pulse.

It should be noted that because the first pole plate 51 is electrically connected to the radio frequency power device 4 and the second pole plate 52 is grounded, when the radio frequency power device 4 is activated, a plasma will be generated between the first and second pole plates 51 and 52. The plasma thus produced facilitates deposition of the ablated target on the substrate (S).

Preferably, the film deposition apparatus further includes a gas supply unit (not shown) that is connected to the chamber 2 and is used to deliver a gas into the chamber 2.

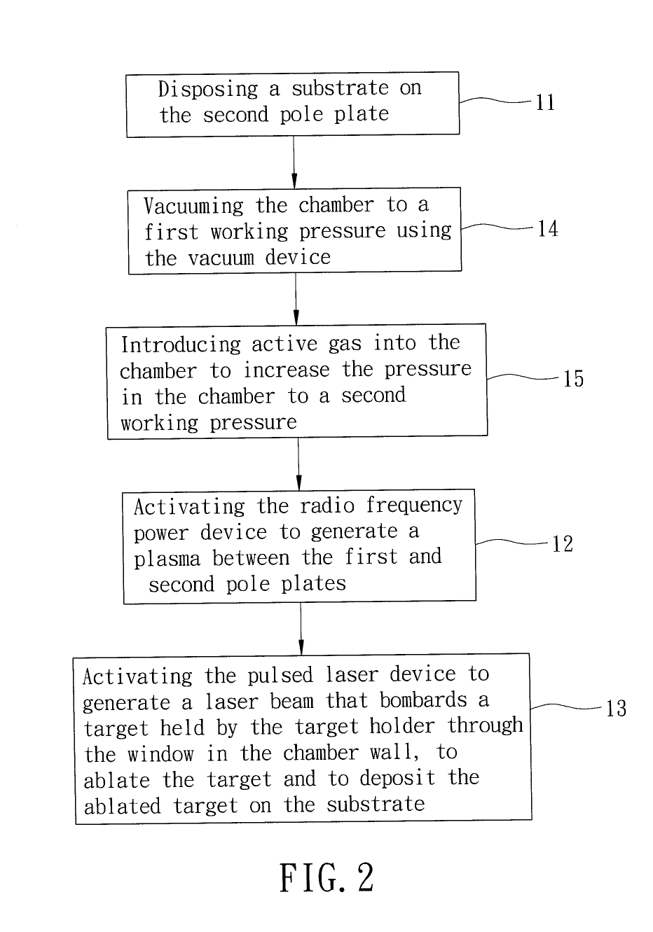

FIG. 2 illustrates a film deposition method using the film deposition apparatus according to this invention. The method comprises:

(a) disposing a substrate (S) on the second pole plate 52;

(b) vacuuming the chamber 2 to a first working pressure using the vacuum device 6;

(c) activating the radio frequency power device 4 to generate a plasma between the first and second pole plates 51 and 52; and

(d) activating the pulsed laser device 7 to generate a laser beam that bombards the target 32 held by the target holder 3 through the window 22 in the chamber wall 21 to ablate the target 32 and to deposit the ablated target on the substrate (S).

In the examples of this invention, the target 32 is zinc oxide, and is made by the steps of ball milling, sintering and tablet compressing.

Preferably, the method further comprises, between step (b) and step (c), a step (e) of introducing an active gas into the chamber 2 using the gas supply unit to increase the pressure in the chamber 2 to a second working pressure.

Preferably, the first working pressure ranges from 30 mtorr to 50 mtorr, and the second working pressure ranges from 100 mtorr to 300 mtorr.

It is worth to mention that the active gas may be able to chemically react with the ablated target so as to modify the film property.

Preferably, the active gas is oxygen.

### EXAMPLES

Two comparative examples (CE1 and CE2) and seven examples (E1, E2, E3, E4, E5, E6 and E7) are provided for illustration.

### Comparative Example 1 (CE1)

A substrate (S), such as silicon wafer, was immersed in methanol, de-ionized water, acetone, and de-ionized water in sequence, and cleaned using an ultrasonic oscillator for ten minutes, followed by blowing using nitrogen gas and heating in a high temperature furnace to remove residual moisture. The immersion and cleaning steps could be repeated several times to completely remove pollutants on the substrate (S). The cleaned substrate (S) was placed on a second pole plate 52 in a chamber 2. The chamber 2 was vacuumed to 30 mtorr, and argon was introduced into the chamber 2 and the pressure in the chamber 2 was maintained at 100 mtorr. The radio frequency power device 4 was activated to provide 21 Watt of output power so as to generate a plasma. The plasma was generated for five minutes to clean the chamber 2 and the substrate (S). After cleaning, the radio frequency power device 4 was turned off, and the cleaning stage prior to the film deposition method according to this invention was thus completed.

Then, the chamber 2 was vacuumed to a working pressure of 50 mtorr. The pulsed laser device 7 was then activated to provide a laser beam with a wavelength of 532 nm and a laser power of 33 mJ/pulse to perform film deposition for sixty minutes. In CE1, the first pole plate 51 had a diameter of 8 cm, and the second pole plate 52 had a diameter of 20 cm.

### Comparative Example 2 (CE2)

The film deposition method in CE2 was similar to that of CE1 except that, after the cleaning stage was completed and before the pulsed laser device 7 was activated, oxygen was directed into the chamber 2 to increase the pressure in the chamber 2 to a second working pressure of 100 mtorr.

### Example 1 (E1)

The film deposition method of E1 was similar to that of CE1 except that, after the cleaning stage was completed and before the pulsed laser device 7 was activated, the radio frequency power device 4 with an output power of 52 Watt was activated.

### Example 2 (E2)

The film deposition method in E2 was similar to that of E1 except that the output power of the radio frequency power device 4 was 10 Watt.

### Example 3 (E3)

The film deposition method in E3 was similar to that of E1 except that the output power of the radio frequency power device 4 was 31 Watt.

### Example 4 (E4)

The film deposition method in E4 was similar to that of E3 except that the first pole plate 51 had a diameter of 5 cm.

### Example 5 (E5)

The film deposition method in E5 was similar to that of E3 except that the first pole plate 51 had a diameter of 12 cm.

### Example 6 (E6)

The film deposition method in E6 was similar to that of E3 except that the first pole plate 51 had a diameter of 15 cm.

### Example 7 (E7)

The film deposition method in E7 was similar to that of E3 except that, after the cleaning stage was completed and before the radio frequency power device 4 was activated, oxygen was directed into the chamber 2 such that the chamber 2 had a second working pressure of 100 mtorr.

### <Data Analysis>

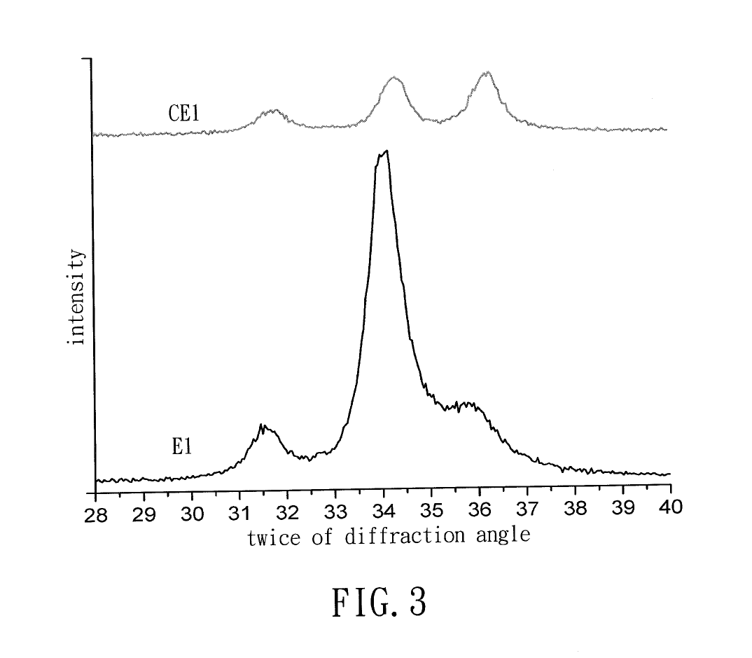

FIG. 3 illustrates that the zinc oxide film formed in E1 has a better crystallinity than that of CE1 since the peak intensity of the zinc oxide film of E1 is larger than that of CE1.

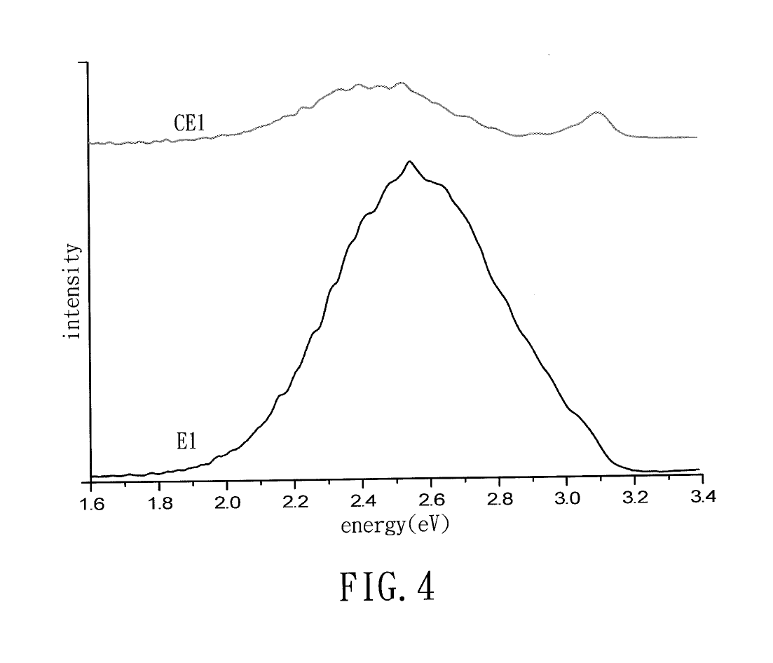

FIG. 4 illustrates that the zinc oxide film of E1 has a better photoluminescence than that of CE1 since the peak intensity of the zinc oxide film of E1 is larger than that of CE1.

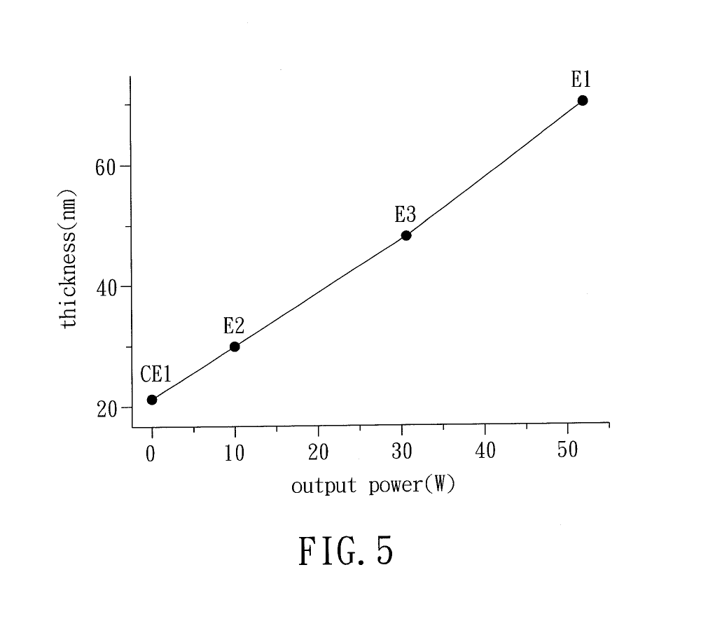

As shown in FIG. 5, it is revealed that each of the zinc oxide films of E1, E2, and E3 has a thickness larger than that of CE1, which indicates that plasma generated by the radio frequency power device 4 facilitates film deposition. The data also shows that the thickness of the film is increased with an increase in radio frequency output power.

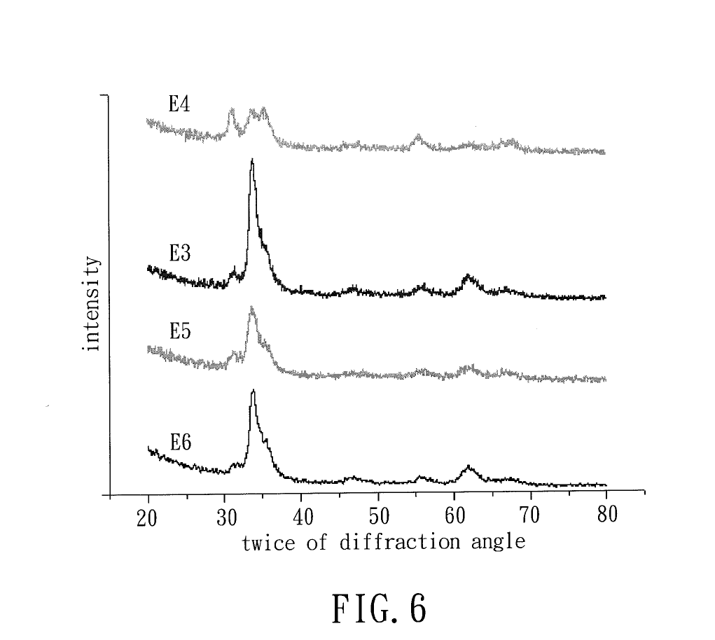

FIG. 6 illustrates XRD spectra for the zinc oxide films of E3, E4, E5 and E6, in which the zinc oxide film of E3 has the greatest crystallinity, which indicates that the sizes of the first and second pole plates 51, 52 affect the crystal structure of the zinc oxide film. Preferably, the ratio of the diameter of the first pole plate 51 to the diameter of the second pole plate 52 is 8:20.

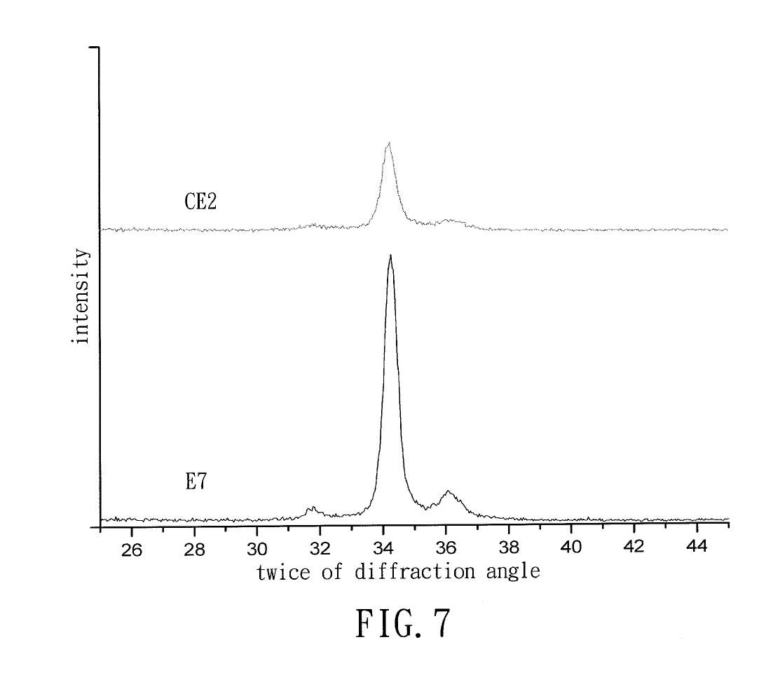

FIG. 7 shows XRD spectra for the zinc oxide films of CE2 and E7. From FIG. 7, it is revealed that the zinc oxide film of E7 has superior crystallinity over that of CE2, which indicates that plasma generated by the radio frequency power device 4 facilitates film deposition.

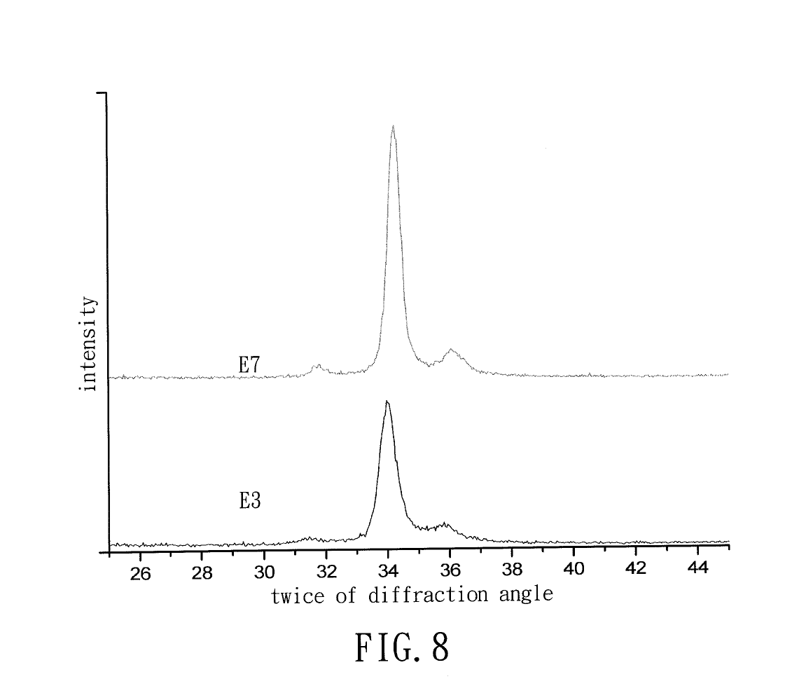

FIG. 8 shows XRD spectra for the zinc oxide films of E3 and E7. The data shows that introduction of active gas, e.g., oxygen, into the chamber 2 could improve crystallinity of the zinc oxide film.

To sum up, by virtue of combination of the radio frequency power device 4 with the pulsed laser device 7, the film deposition method of the present invention can be conducted at a relatively low vacuum degree, e.g., 30 mtorr to 300 mtorr, and room temperature. The plasma generated by the radio frequency power device 4 facilitates deposition of the zinc oxide film, and thus the zinc oxide film made by the method of this invention exhibits superior crystallinity. Moreover, the crystallinity of the zinc oxide film can be improved by introducing active gas or adjusting the ratio of the sizes of the first and second pole plates 51, 52. It should be noted that the film deposition method and apparatus of the present invention can also be performed at a high vacuum degree and a high temperature, and the films made under such conditions would have superior property over those made at low vacuum degree and room temperature.

While the present invention has been described in connection with what are considered the most practical and preferred embodiments, it is understood that this invention is not limited to the disclosed embodiments but is intended to cover various arrangements included within the spirit and scope of the broadest interpretations and equivalent arrangements.

What is claimed is:

1. A film deposition apparatus for depositing a film on a substrate, comprising:
a chamber including a chamber wall that is formed with a window;
a target holder disposed in said chamber for supporting a target;
a radio frequency power device;
a pole plate unit disposed in said chamber and including a first pole plate that is electrically connected to said radio frequency power device, and a second pole plate for supporting the substrate, said first and second pole plates being disposed at two opposite sides of said target holder;
a vacuum device for extracting air from said chamber; and
a pulsed laser device to generate a laser beam capable of bombarding the target through said window.

2. The film deposition apparatus of claim 1, wherein said target holder includes a rotatable base connected to said chamber wall and having a free end for supporting the target.

3. The film deposition apparatus of claim 1, wherein said laser beam has a wavelength ranging from 150 nm to 1100 nm.

4. The film deposition apparatus of claim 1, wherein said first pole plate has a size smaller than that of said second pole plate.

5. A film deposition method using the film deposition apparatus of claim 1, comprising:
(a) disposing a substrate on the second pole plate;
(b) vacuuming the chamber to a first working pressure using the vacuum device;
(c) activating the radio frequency power device to generate a plasma between the first and second pole plates; and
(d) activating the pulsed laser device to generate a laser beam that bombards a target held by the target holder through the window in the chamber wall, to ablate the target and to deposit the ablated target on the substrate.

6. The film deposition method of claim 5, further comprising, between step (b) and step (c), a step (e) of introducing an active gas into said chamber to increase the pressure in the chamber to a second working pressure.

7. The film deposition method of claim 5, wherein the first working pressure ranges from 30 mtorr to 50 mtorr, the second working pressure ranging from 100 mtorr to 300 mtorr.

8. The film deposition method of claim 5, wherein the target is made of a metal oxide material.

9. The film deposition method of claim 8, wherein the metal oxide material is selected from the group consisting of zinc oxide, tin(II) oxide, and indium tin oxide.
